(19) United States
(12) Patent Application Publication
(10) Pub. No.: US 2013/0123112 A1
(43) Pub. Date: May 16, 2013

(54) METHOD AND ARRANGEMENT FOR PRODUCING SUPERCONDUCTING LAYERS ON SUBSTRATES

(71) Applicant: Tabea Arndt, Erlangen (DE)

(72) Inventor: Tabea Arndt, Erlangen (DE)

(21) Appl. No.: 13/811,591

(22) PCT Filed: May 16, 2011
(86) PCT No.: PCT/EP2011/057875

§ 371 Date: Jan. 22, 2013

(30) Foreign Application Priority Data
Jul. 21, 2010 (DE) 10 2010 031 741.1

(51) Int. Cl. H01L 39/24

(52) U.S. Cl. CPC H01L 39/2487
USPC 505/470; 118/300; 427/62

(57) ABSTRACT

A continuous process produces superconducting layers on substrates, such as a superconducting layer of MgB₂ produced by aerosol deposition on the substrate.

### CROSS REFERENCE TO RELATED APPLICATIONS

This application is the U.S. national stage of International Application No. PCT/EP2011/057875, filed May 16, 2011 and claims the benefit thereof. The International Application claims the benefit of German Application No. 102010031741.1 filed on Jul. 21, 2010, both applications are incorporated by reference herein in their entirety.

### BACKGROUND

A disadvantage of the described method is that with the described structure it is only possible to coat discrete substrates in succession, i.e. with a time delay, and a great deal of time and energy must be expended in order to introduce the substrate into the chamber, generate the vacuum and remove the coated substrates from the chamber, which incurs costs.

### SUMMARY

Described below are a method and an arrangement for producing superconducting layers on substrates, which do not require discrete deposition of the superconducting material successively with a time delay, and which entail little outlay and low costs. The method is able to reliably deposit superconducting layers continuously with low energy consumption, for example on material in web form, without experiencing contamination of the superconducting material, for example due to enhanced diffusion at copper at high temperatures.

In the method a superconducting layer of MgB₂ may be produced on the substrate by aerosol deposition. The method is carried out as a continuous process.

This makes it possible to produce long superconducting wires or cables. The aerosol deposition does not require a high vacuum, so that outlay and costs can be kept low. Low temperatures in the region of room temperature permit deposition with low energy consumption and without contamination of the superconducting material, for example due to enhanced diffusion of copper at high temperatures.

The continuous process may be carried out as a continuous-throughput process, in particular with a substrate which is provided continuously from a roll. As an alternative to a roll, the material may also be unwound from a differently shaped carrier or provided in coil form without a carrier. The use of a roll leads to unimpeded delivery of the substrate for the aerosol deposition without knotting or tangling of the substrate.

The substrate may be provided in the form of webs and, in the case of very long substrates in the form of webs, unwound well e.g. from a roll. Continuous delivery of substrate to the deposition process can thereby be ensured. The term webs refers to elongate substrates in strip form, particularly with a rectangular cross section. The webs have a flat upper side, on which the superconducting material can be deposited. The upper side may in particular extend over a much larger area than the side faces.

A metal substrate may be used, in particular a substrate formed of copper or steel. Copper has good electrical properties, for example for bridging defects in the superconducting material as a bypass. Steel, on the other hand, has a higher mechanical stability. Combinations of materials, particularly in laminated form or as alloys, are also possible.

The superconducting layer may be produced from MgB₂ powder. As an alternative, the superconducting material may be produced from a powder mixture of Mg and B, which is reacted subsequently i.e. after the aerosol deposition to form MgB₂. A heat retreatment after the aerosol deposition, for example in the range of more than 800° C., may be used in this case. When using MgB₂ powder as starting material, a heat retreatment as described above may also be used to improve the superconducting or electrical properties of the deposited layer. Production without heating to high temperatures, for example higher than 800° C., is likewise possible when using the aerosol deposition method, so that for example it is possible to use a copper substrate without a diffusion barrier layer between the copper and the superconducting material, without contaminating diffusion of copper into the superconducting material. The superconducting material may also be produced from MgB₂ powder and/or Mg and B powder mixed with shunt material, in particular an FeCr-Ni or Cu-Ni alloy. The shunt material then ensures good electrical bridging of defects in the superconducting material and good electrical connection between the superconducting crystallites.

Helium, nitrogen or air may be used as a carrier gas for the aerosol production and aerosol deposition. Nitrogen is more economical and, in contrast to air, does not entail the risk of oxidation of substances involved in the method.

The method may be carried out essentially at room temperature, in particular at 25° C. This offers the advantages already described above, such as low costs, low energy outlay and reduced or zero diffusion of substances such as copper into the superconducting material, and therefore no contamination of the superconducting material. In this way, for example, the use of copper as a substrate without a diffusion barrier layer is made possible for the first time.

The superconducting layer may be produced with a layer thickness greater than or equal to 1 μm. Specifically in comparison with other deposition methods, the aerosol deposition method makes it possible to produce thicker layers, particularly in a short time and with low cost outlay.

The method may be carried out in a coating chamber which has at least one air lock, in particular an air lock for supplying the substrate and an air lock for removing the substrate, i.e. two air locks for separation of the interior of the coating chamber from the atmosphere surrounding the coating chamber. In this way, it is possible to operate with desired pressures and, for example, in a protective gas atmosphere, and/or contamination due e.g. to dirt or dust from the environment can be prevented. By use of the air locks, the coating system is sealed from the surroundings and the layers can be produced without contamination.

As an alternative, the method may also be carried out in an arrangement which is fully encapsulated from the environment, in particular for airtight isolation of the method from the atmosphere surrounding the arrangement.

In this way, the arrangement may directly contain a source roll of substrate and/or a target roll for the coated substrate in the encapsulated space, so that continuously operated air locks for the substrate and the coated substrate can be obviated. Air locks may still be used to equip the system for example with a substrate roll and for removing the roll of finally coated substrate. These, however, are technically simpler to configure than continuously operating air locks as were described in the example above. The other advantages are similar to the example described above.

The aerosol deposition may be followed by a further coating process, in particular coating to produce a copper and/or aluminum layer. This layer may be used as a bypass in order to sustain normal electrical conduction in the event of collapse of the superconductivity and/or in order to bridge defects in the superconducting layer. The layer may also be used for further mechanical stabilization. An insulation process may subsequently be carried out.

As an alternative, an insulation process may be carried out immediately after the aerosol deposition. A superconducting cable or a superconducting wire is therefore produced, without further steps, and is electrically insulated from the environment.

First, in the method for producing superconducting layers on substrates, a carrier gas may enter an aerosol chamber through a gas-permeable support, powder which is taken up in particle form by the carrier gas when it flows through the support being arranged on the support. Second, the carrier gas/powder mixture may be introduced into a coating chamber through a nozzle, in particular a regulable or controllable nozzle, particularly a nozzle in slit form, the powder being deposited by an aerosol deposition process on a substrate moved continuously through the coating chamber.

Chronologically between the first and second steps, an aerosol of powder and carrier gas may flow through a conditioner, in which powder particles which are too large for the deposition are filtered out and/or harmonization of the kinetic energy of the powder particles takes place. In this way, the superconducting layer produced is more uniform in terms of its structure and has better electrical properties imparted to it.

An arrangement for producing superconducting layers on substrates may have a coating chamber having at least one entry for a substrate in web form and having at least one exit for the substrate in web form coated with a superconducting layer. The arrangement may furthermore include a device for providing an aerosol for coating the substrate with MgB₂. A method as described above may be carried out with the arrangement, the advantages described above for the method likewise applying for the arrangement.

### BRIEF DESCRIPTION OF THE DRAWINGS

These and other aspects and advantages will become more apparent and more readily appreciated from the following description of the exemplary embodiments, taken in conjunction with the accompanying drawings of which:

FIG. 1 is a schematic sectional representation of an arrangement 1 for producing superconducting layers on substrates 15 by aerosol deposition, and

FIG. 2 is a schematic sectional representation of the arrangement 1 of FIG. 1, but fully encapsulated.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

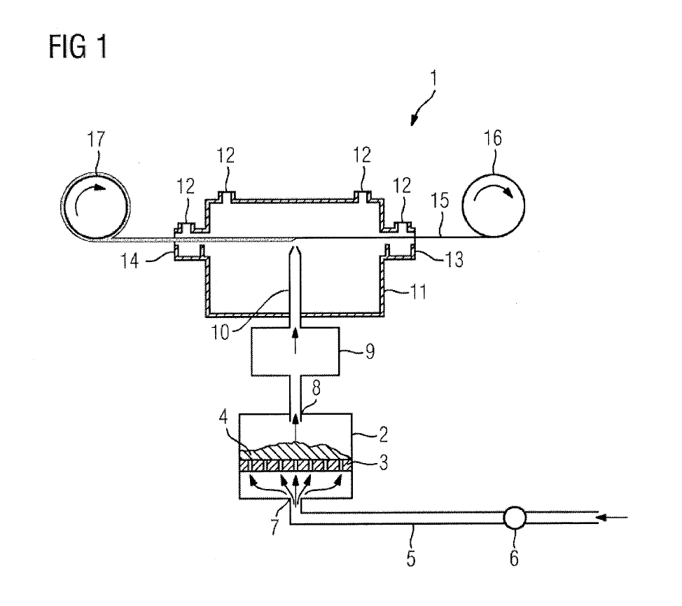

FIG. 1 shows a schematic sectional representation of the arrangement 1 for producing superconducting layers on substrates 15 by aerosol deposition. The method as described above may be carried out with this arrangement 1.

The arrangement 1 includes an aerosol chamber 2 for producing an aerosol from a powder 4 and a carrier gas. The carrier gas is delivered to the aerosol chamber 2 through a carrier gas supply line 5. For example, nitrogen may be used as the carrier gas. The influx and therefore the pressure and, on the entry side, the mass flow rate of the carrier gas is regulated or controlled by a gas regulator 6, which is installed in the carrier gas supply line 5. The carrier gas flows through an entry 7 into the aerosol chamber 2. The entry 7 is arranged at the lower end of the aerosol chamber 2. In the aerosol chamber 2, the carrier gas flows upward from below through a gas-permeable support 3, on which a powder is arranged. The powder may, for example, include MgB₂ particles. From the gas-permeable support 3, the carrier gas flows through the powder and entrains powder particles with it by virtue of the flow. An aerosol is thereby formed. The aerosol, formed of carrier gas and particles, leaves the aerosol chamber 2 at the upper end through an exit 8. Connected by a pipeline or attached directly to the aerosol chamber 2, in particular fluid-tightly, there is a conditioner 9. The aerosol flows through the conditioner 9, excessively large particles being filtered out and harmonization of the kinetic energy of the particles remaining in the aerosol taking place. An arrangement may, however, also be constructed without a conditioner 9. The structure is thereby simplified, but the deposited layer is then less uniform with inferior electrical, in particular superconducting, properties.

From the conditioner 9, the aerosol flows through a nozzle 10, which may be formed as a slit at an exit end, in a coating chamber 11 onto the substrate 15 to be coated. The substrate 15 may, for example, be a steel web with a thickness in the range of micrometers and a width in the range of millimeters. The substrate 15 may, however, also have different shapes, for example the shape of a wire with a round cross section. In the case of a substrate 15 in web form with a rectangular cross section, referred to below merely as a substrate 15 in web form, the exit of the nozzle 10 is directed at a surface of the substrate web 15 which, for example, extends over several millimeters in width in contrast to a side face of the substrate web 15 having a width in the range of micrometers. This wide flat side of the substrate 15 is then coated with the particle material when the particles of the aerosol strike it, for example with MgB₂ crystallite particles. The powder particles remain “stuck” or adhering on the substrate 15 and thus form a continuous superconducting layer on one side of the substrate 15.

The substrate 15 in web form is unwound continuously from a roll 16, i.e. the source roll, moves through an entry air lock 13 into the coating chamber 11 and moves past the nozzle 10 through an exit air lock 14 out of the coating chamber 11, in order to be rewound on a roll 17, i.e. the target roll. The two rolls 16, 17 may be driven in the same way and move with the same rotation sense and the same rotation speed. As an alternative, only one roll may be driven, for example the target roll 17, the substrate web 15 being unwound from the source roll 16 by tensile force, or, with a driven source roll 16, the substrate 15 may be wound on the target roll 17 by compressive force.

In order to produce a uniform superconducting layer, that is to say one with uniform thickness distributed over a full side of the substrate 15, the forward feed rate of the substrate 15, i.e. the circumferential rotation speed of the rolls 16, 17, should be constant throughout the entire coating process. The nozzle 10 should deliver the aerosol with a uniform flow rate, and the particle number and size should not vary, or not vary greatly, in the aerosol. It is also advantageous to use a nozzle 10 in slit form, for which the longitudinal direction of the slit is arranged parallel to the width and surface of the side of the substrate web 15 to be coated. The formation of uniform layers is also promoted by the aerosol being delivered uniformly over the length of the slit, so that it can be deposited uniformly on the surface of the substrate web 15 arranged opposite the slit.

Optionally, as represented in FIG. 1, evacuation ports 12 through which the chamber 11 and/or the air locks 13 and 14 can be evacuated are provided in the coating chamber 11. As an alternative, a protective gas, for example nitrogen, may be supplied through the ports 12. In this way, either a reduced pressure up to the extent of a vacuum, or a protective gas atmosphere, may be generated in the coating chamber 11. Contaminations of the superconducting layer by particles or constituents of the ambient air can thus be prevented. Oxidation of constituents of the particles in the aerosol, and therefore of the superconducting layer, can also be prevented.

A simpler structure of the arrangement, without evacuation ports 12 and/or air locks 13, 14, is however also possible. Under certain circumstances, even a coating chamber 11 is not categorically necessary when the effect of ambient air does not interfere with the deposition of the aerosol and the formation of the superconducting layer. Although a vacuum may be advantageous, a high vacuum is not however necessary. The method may even be carried out at atmospheric or ambient pressure.

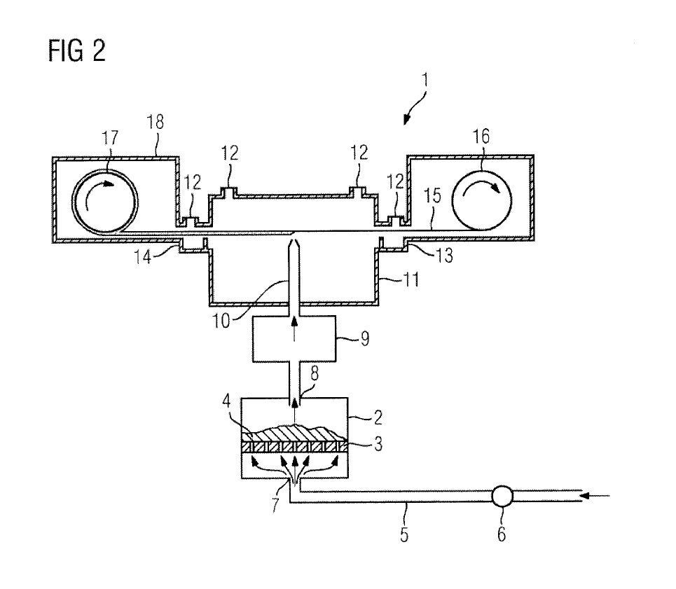

FIG. 2 represents an alternative embodiment of the arrangement 1. The arrangement 1 in FIG. 2 is formed in a similar way to the arrangement 1 shown in FIG. 1, but in addition with fully encapsulated source and target rolls 16, 17. The interior of the entire arrangement can therefore be sealed in an airtight fashion and, for example, evacuable or fillable with protective gas atmosphere through evacuation ports 12, as described above. Oxidation or contamination with dust and dirt particles of the substrate 15 coated with a superconducting layer can thus be prevented by the encapsulation 18, even when winding and unwinding. Air locks (not represented) may be provided in order to supply a complete roll 16, 17 to the arrangement or remove it therefrom.

Exemplary embodiments described above may also be combined. For example, only one roll 17 may be encapsulated while the substrate web 15 is supplied from a roll 16 to the coating chamber 11 through an air lock. In the event of full encapsulation 18 of the arrangement, air locks 13 and 14 for supplying the substrate web 15 to the coating chamber 11, and removing it therefrom, may even be obviated.

The method described above and the arrangements for carrying out the method, permit uniform coating of substrates, for example in web form, with MgB₂ superconducting layers over long lengths. Thus, the substrate webs may have lengths in the range of from centimeters to several hundred meters. The deposited layers can be produced with uniform thicknesses and electrically uniform properties, over the entire length of the substrate web, at room temperature. New structures of the substrate webs with superconducting layers are therefore possible, which for example are formed of copper and do not require any intermediate layers as a diffusion barrier between the substrate and the superconducting layer. The low deposition temperature and the low demands on the pressure conditions during the deposition (high vacuum not necessary) lead to an energy-saving in comparison with conventional processes, such as sputtering. Thick layers can be produced by the method with a high throughput, i.e. in a short time.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-15. (canceled)

16. A method for producing superconducting layers on substrates, comprising:
a continuous process producing a superconducting layer of MgB₂ on the substrate by aerosol deposition.

17. The method as claimed in claim 16, wherein the continuous process is a continuous-throughput process in which the substrate is provided continuously from a roll.

18. The method as claimed in claim 17, wherein the substrate has a web form.

19. The method as claimed in claim 17, wherein the substrate is selected from the group consisting of copper and steel.

20. The method as claimed in claim 17,
wherein the aerosol deposition producing the superconducting layer uses an aerosol carrying a powder selected from the group consisting of MgB₂ powder, a powder mixture of Mg and B, MgB₂ powder mixed with shunt material, and a powder mixture of Mg and B mixed with shunt material, and
wherein the shunt material when used is selected from the group consisting of FeCr-Ni alloy and Cu-Ni alloy.

21. The method as claimed in claim 20, wherein the aerosol includes a carrier gas selected from the group consisting of helium, nitrogen and air.

22. The method as claimed in claim 21, wherein the method is carried out substantially at 25° C.

23. The method as claimed in claim 22, wherein the superconducting layer is produced with a layer thickness of at least 1 μm.

24. The method as claimed in claim 23, wherein the method is carried out in a coating chamber having at least one air lock to supply the substrate and to remove the substrate, thereby separating an interior of the coating chamber from atmosphere surrounding the coating chamber.

25. The method as claimed in claim 23,
further comprising at least one of supplying a source roll of the substrate and producing a target roll of a coated substrate, and
wherein the method is performed inside a fully encapsulated environment for airtight isolation of said continuous process producing the superconducting layer and said at least one of supplying the source roll of the substrate and producing the target roll, from an atmosphere surrounding the arrangement.

26. The method as claimed in claim 23, further comprising performing a further coating process, to produce at least one of a copper and an aluminum layer.

27. The method as claimed in claim 23, further comprising performing an insulation process immediately after the aerosol deposition.

28. The method as claimed in claim 23, wherein the continuous process comprises:
supplying a carrier gas to an aerosol chamber through a gas-permeable support from which powder is taken up in particle form by the carrier gas when it flows through the support, thereby producing a carrier gas/powder mixture; and
introducing the carrier gas/powder mixture into a coating chamber through a regulable or controllable slit nozzle while the substrate is moved continuously through the coating chamber, so that the powder is deposited by the aerosol deposition process on the substrate.

29. The method as claimed in claim 28, wherein the continuous process further comprises conditioning the carrier gas/powder mixture, between said supplying and said introducing, by the carrier gas/powder mixture flowing through a conditioner to at least one of filter out powder particles that are too large for the aerosol deposition process and harmonization of kinetic energy of the powder particles.

30. An arrangement for producing superconducting layers on substrates by a continuous process, comprising:
a coating chamber having at least one entry for a substrate in web form and having at least one exit for the substrate in web form coated with a superconducting layer of MgB₂; and
a device providing an aerosol that coats the substrate with MgB₂ by aerosol deposition.
